(19) United States
(12) Patent Application Publication
(10) Pub. No.: US 2014/0091450 A1
(43) Pub. Date: Apr. 3, 2014

(54) Semiconductor Housing for Smart Cards

(71) Applicant: Infineon Technologies AG, Neubiberg (DE)

(72) Inventors: Frank Pueschner, Kelheim (DE); Juergen Hoegerl, Regensburg (DE); Peter Scherl, Regensburg (DE); Thomas Spoettl, Mintraching (DE)

(21) Appl. No.: 14/035,579

(22) Filed: Sep. 24, 2013

(30) Foreign Application Priority Data
Sep. 25, 2012 (DE) 102012018928.1

(51) Int. Cl. H01L 23/538

(52) U.S. Cl. CPC H01L 23/5388
USPC 257/679

(57) ABSTRACT

A semiconductor housing includes a front side with a semiconductor chip and a first metallization on a substrate, and a rear side with a second metallization. The rear side is situated opposite the front side of the semiconductor housing. The semiconductor housing further includes a first compensation layer applied on the front side of the semiconductor housing.

### PRIORITY CLAIM

This application claims priority to German Patent Application No. 10 2012 018 928.1, filed on 25 Sep. 2012, the content of said German application incorporated herein by reference in its entirety.

### BACKGROUND

Contactless smart card housings are being developed on a new housing platform. This housing platform is significantly more cost-effective to produce. The housing platform is also known as CoCIS (Coil on Chip In Substrate). In this case, the housing consists of a substrate, for example polyamide tape with a double-sided metallization in continuous coil form, which serves as an antenna. In this case, a chip is fixed on the top side using FCOS technology—FCOS stands for Flip Chip On Substrate. This housing is then laminated vertically and centrally into a smart card using a multilayer technology by the card manufacturer. In this case, the signal coupling between the housing and the card antenna is effected contactlessly by means of the antenna of the housing and the antenna of the smart card.

One crucial quality feature during smart card production here is that the installation position of the housing in the smart card is not visible, inter alia for security-relevant reasons, and that the card surface is as planar as possible for subsequent post-processing (embossing steps, etc.). In order to achieve this, nowadays CoCIS housings are incorporated in a two-ply core layer. These preferably consist, at least partly, of the material polycarbonate. In this case, a cutout for the chip is situated in the upper ply, and a cutout for the substrate, that is to say the chip carrier, is situated in the lower ply. In this case, the total thickness is somewhat greater than the thickness of the housing to be implemented. During lamination, therefore, the cutouts are intended to be filled with the housing and material of the core layer and a planar card surface is thus intended to arise. However, this is the case only to a limited extent. The card body still stands out at the card surface and, consequently, a planar surface does not arise either.

### SUMMARY

According to embodiments described herein, a housing is provided by means of which, after integration into a smart card, a planar surface of the smart card is formed.

In one embodiment, the semiconductor housing comprises a substrate with a front side and with a chip and a first metallization and a rear side with a second metallization, the rear side being situated opposite the front side of the substrate. A first compensation layer is applied on the front side of the semiconductor housing. The compensation layer on the front side of the housing has the effect that the topography of the CoCIS semiconductor housing is significantly reduced and thus constitutes a planar and compact semiconductor housing structure. As a result, after the housing has been implemented in a smart card, a planar card surface can be obtained.

In one embodiment, the semiconductor housing comprises a first compensation layer having a thickness D1. The thickness D1 is set in such a way that the top side of the chip forms a planar surface with the compensation layer. As a result, the semiconductor housing has a particularly planar and compact semiconductor housing structure. Consequently, after the semiconductor housing has been implemented in a smart card, a particularly planar card surface can be obtained. The semiconductor housing is therefore no longer visible in the smart card body on account of a lack of surface unevennesses.

In a further embodiment, the semiconductor housing has a second compensation layer on its rear side. As a result, the compensation volume subsequently to be kept available for flush embedding into the smart card is significantly reduced and, consequently, a single-ply core layer can be used for example instead of a two-ply core layer.

In one embodiment, the semiconductor housing has a second compensation layer on its rear side. The second compensation layer has a thickness D2 set in such a way that the second metallization forms a planar surface with the second compensation layer. As a result, the compensation volume subsequently to be kept available for flush embedding into the smart card is significantly reduced and, consequently, a single-ply core layer can be used for example instead of a two-ply core layer and particularly planar card surfaces of smart cards can thereby be realized.

In one embodiment, the semiconductor housing has a contactless smart card housing, wherein the first and second metallizations are embodied in continuous coil form, and wherein the chip is fixed using FCOS technology. As a result, a particularly compact, robust and cost-effective semiconductor housings can be realized.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 shows a semiconductor housing laminated in core layers, wherein the structures of the semiconductor housing clearly stand out at the surface of the card body.

FIG. 2 shows, in principle, the lamination of compensation layers on both sides of the semiconductor housings prior to singulation, which are arranged on a long tape.

FIG. 3 shows a semiconductor housing with laminated compensation layers on the front and rear side of the semiconductor housing.

FIG. 4 shows a semiconductor housing with a laminated compensation layer laminated into a card body with an antenna.

FIG. 5 shows a further embodiment of a semiconductor housing with a laminated compensation layer laminated into a card body.

### DETAILED DESCRIPTION

Exemplary embodiments of the invention are explained in greater detail below, with reference to the accompanying figures. However, the invention is not restricted to the embodiments specifically described, but rather can be modified and altered in a suitable way. It lies within the scope of the invention to suitably combine individual features and feature combinations of one embodiment with features and feature combinations of another embodiment in order to arrive at further embodiments according to the invention.

Before the exemplary embodiments of the present invention are explained in greater detail below with reference to the figures, it is pointed out that identical elements in the figures are provided with the same or similar reference signs and that a repeated description of these elements is omitted. Furthermore, the figures are not necessarily true to scale. Rather, the main emphasis is on elucidating the basic principle.

FIG. 1 shows a semiconductor housing 200 such as is known from the prior art. The semiconductor housing 200 comprises a chip 50 and laminated in core layers 100 which form the card body 100. The structures of the semiconductor housing 10 clearly stand out at the surface of the card body 100.

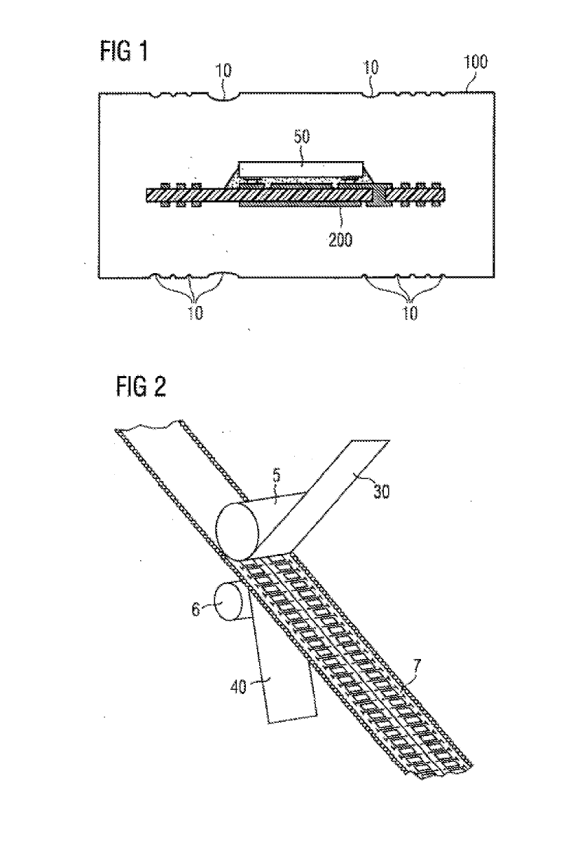

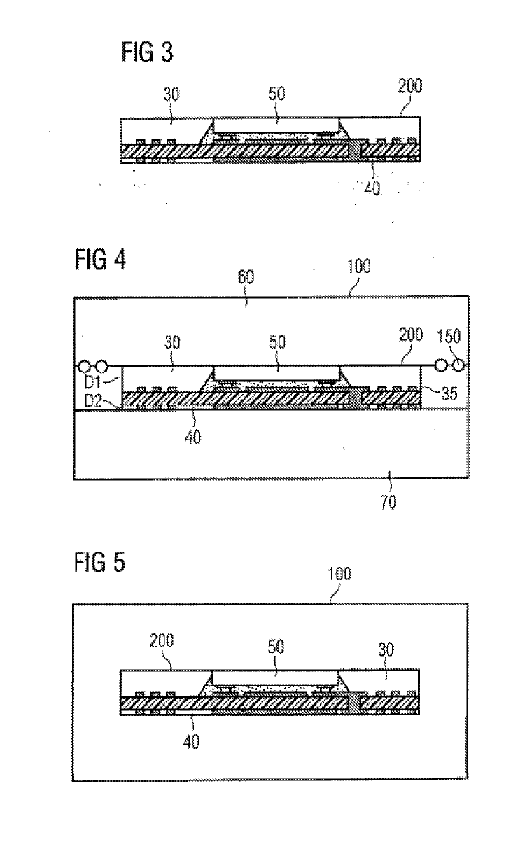

FIG. 2 shows, in principle, a method in which compensation layers 30, 40 are laminated onto the two sides of a carrier of semiconductor housings 7, which can be for example a long plastic tape composed of polyamide. The compensation layers 30, 40 are in this case heated and applied to the carrier of the semiconductor housings 7 and thus to the semiconductor housings 200 by means of pressure rollers. In a further subsequent work step, the semiconductor housings 7 are singulated by cutting, sawing or by means of a laser and lateral straight cut edges 35 (shown in FIG. 3) of the semiconductor housing 200 are thereby ensured, as illustrated in FIG. 3.

FIG. 3 shows a semiconductor housing 200 with laminated compensation layers 30, 40 on the front and rear sides of the semiconductor housing 200. The compensation layers 30, 40 can be laminated onto the semiconductor housing 200 by means of a method as described in FIG. 2. In a further embodiment, the semiconductor housing 200 can have only one compensation layer 30 on the front side. The thicknesses D1 and D2 and material properties of the compensation layers 30, 40 are chosen in such a way that ideally a layer flush with the rear side of the chip 50 arises on the front side of the semiconductor housing 200 and that a layer flush with the second metallization arises on the rear side of the semiconductor housing 200.

FIG. 4 shows semiconductor housings 200 with laminated compensation layers 30, 40 laminated into a card body 100 with an antenna 150. The card body 100 is formed by means of two core layers 60, 70. In this case, one of the core layers 60, 70 can have a cutout that receives the semiconductor housing 200. In a further embodiment, one of the core layers 60, 70 can have a cutout that receives the side with the chip 50 of the semiconductor housing 200 and the other core layer 60, 70 can have a cutout that has the side of the semiconductor housing 200 with the second metallization plane. In one embodiment, only one core layer 60, 70 can have a cutout that receives the entire semiconductor housing 200 in the core layer. This embodiment of the smart card body 100 can be realized ideally when a compensation layer 40 is laminated on the rear side of the semiconductor housing 200. The card body 100 can furthermore have an antenna 150. The antenna 150 can be designed as a contactless booster antenna. As a result, the signal coupling between the semiconductor housing 200 and the antenna 150 of the card body 100 can be effected contactlessly. As a result, the production of a card body 100 with an integrated semiconductor housing 200 is significantly simplified since the antenna 150 of the card body 100 does not have to be contact-connected to the semiconductor housing 200 in a complex manner.

FIG. 5 shows a card body 100 with an integrated semiconductor housing 200 with a chip 50 and laminated compensation layers 30, 40. On account of the laminated compensation layers 30, 40, the card body 100 has no structures on its surface. Consequently, the smart card body 100 can be processed further very easily on account of its smooth surface.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A semiconductor housing, comprising:
a front side with a semiconductor chip and a first metallization on a substrate;
a rear side with a second metallization, the rear side being situated opposite the front side; and
a first compensation layer applied on the front side of the semiconductor housing.

2. The semiconductor housing of claim 1, wherein the first compensation layer has a thickness such that a top side of the chip forms a planar surface with the first compensation layer.

3. The semiconductor housing of claim 1, further comprising a second compensation layer on the rear side of the semiconductor housing.

4. The semiconductor housing of claim 3, wherein the second compensation layer has a thickness such that the second metallization forms a planar surface with the second compensation layer.

5. The semiconductor housing of claim 1, wherein the semiconductor housing is a contactless smart card module, wherein the first and second metallizations are embodied in continuous coil form, and wherein the semiconductor chip is fixed using FCOS technology.

6. A semiconductor housing, comprising:
a substrate with a first metallization at a first side of the substrate and a second metallization at a second side of the substrate opposite the first side;
a semiconductor chip attached to the first side of the substrate and electrically connected to the first and second metallizations; and
a first compensation layer disposed on the first side of the substrate.

7. The semiconductor housing of claim 6, wherein the first compensation layer forms a planar surface with a side of the semiconductor chip facing away from the substrate.

8. The semiconductor housing of claim 6, further comprising a second compensation layer disposed on the second side of the substrate.

9. The semiconductor housing of claim 8, wherein the second compensation layer forms a planar surface with a side of the second metallization facing away from the substrate.

10. A smart card module, comprising:
a smart card body with opposing planar surfaces;
a semiconductor housing disposed in the smart card body and comprising:
a substrate with a first metallization at a first side of the substrate and a second metallization at a second side of the substrate opposite the first side;
a semiconductor chip attached to the first side of the substrate and electrically connected to the first and second metallizations; and
a first compensation layer disposed on the first side of the substrate and laminated into the smart card body; and
a contactless antenna disposed in the smart card body.

11. The smart card module of claim 10, wherein the first compensation layer forms a planar surface with a side of the semiconductor chip facing away from the substrate.

12. The smart card module of claim 10, wherein the semiconductor housing further comprises a second compensation layer disposed on the second side of the substrate and laminated into the smart card body.

13. The smart card module of claim 12, wherein the second compensation layer forms a planar surface with a side of the second metallization facing away from the substrate.

14. The smart card module of claim 10, wherein the smart card body comprises a first core layer and a second core layer.

15. The smart card module of claim 14, wherein one of the core layers has a cutout that receives the semiconductor housing.

16. The smart card module of claim 14, wherein one of the core layers has a cutout that receives a side of the semiconductor housing with the semiconductor chip and the other core layer has a cutout that receives a side of the semiconductor housing with the second metallization.

17. The smart card module of claim 14, wherein only one of the core layers has a cutout that receives the entire semiconductor housing.
